(19) United States
(12) Patent Application Publication
(10) Pub. No.: US 2016/0071566 A1
(43) Pub. Date: Mar. 10, 2016

(54) SEMICONDUCTOR DEVICE

(71) Applicants: Hiromi NORO, Seoul (KR); Shintaro SAKAI, Seoul (KR)

(72) Inventors: Hiromi NORO, Seoul (KR); Shintaro SAKAI, Seoul (KR)

(21) Appl. No.: 14/627,621

(22) Filed: Feb. 20, 2015

Related U.S. Application Data
(60) Provisional application No. 62/046,045, filed on Sep. 4, 2014.

(51) Int. Cl. G11C 11/16

(52) U.S. Cl. CPC G11C 11/165

(57) ABSTRACT

According to one embodiment, a semiconductor device includes a first pad in a first region between a memory region of a semiconductor chip and a first end portion of the semiconductor chip; a second pad in a second region between the memory region and a second end portion of the semiconductor chip, the second end portion being opposite to the first end portion; an output circuit coupled to the second pad; and a calibration circuit which is coupled to the first pad and regulates an impedance of the output circuit, the calibration circuit including a first circuit in the first region and a second circuit in the second region.

### CROSS-REFERENCE TO RELATED APPLICATIONS

This application claims the benefit of U.S. Provisional Application No. 62/046,045, filed Sep. 4, 2014, the entire contents of which are incorporated herein by reference.

### FIELD

The present embodiment relates to a semiconductor device.

### BACKGROUND

Memory devices using magnetoresistive effect elements for memory elements are attracting attention as next-generation memory devices.

Memory devices (e.g., MRAM) using magnetoresistive effect elements are studied and developed as a substitute memory for volatile memories such as DRAM and SRAM.

### BRIEF DESCRIPTION OF THE DRAWINGS

FIG. 1 is a schematic view of a semiconductor device of an embodiment;

FIG. 2 is a plan view showing a layout of a part of the semiconductor device;

FIG. 3 is a block diagram showing a circuit configuration of the semiconductor device of the present embodiment;

FIG. 4 is a view showing one example of an internal configuration of a memory cell array;

FIG. 5 is a view showing a configuration example of a memory cell;

FIG. 6 is a view showing one example of a configuration of an output buffer circuit;

FIG. 7 is a schematic view showing a configuration example of a calibration circuit in the semiconductor device of the present embodiment;

FIG. 8 is a timing chart to explain an operation example of the semiconductor device of the embodiment;

FIG. 9 is a view to explain a modification of the semiconductor device of the embodiment; and

FIG. 10 is a view to explain another modification of the semiconductor device of the embodiment.

### DETAILED DESCRIPTION

In general, according to one embodiment, a semiconductor device includes a first pad disposed in a first region between a memory region of a semiconductor chip and a first end portion of the semiconductor chip; a second pad disposed in a second region between the memory region and a second end portion of the semiconductor chip, the second end portion being opposite to the first end portion; an output circuit coupled to the second pad; and a calibration circuit which is coupled to the first pad and regulates an impedance of the output circuit, the calibration circuit including a first circuit disposed in the first region and a second circuit disposed in the second region.

Hereinafter, the embodiment will be described with reference to the drawings. It is to be noted that in the following description, elements having the same functions and configurations will be denoted with the same reference symbols, and redundant descriptions will be omitted.

### (1) Embodiment

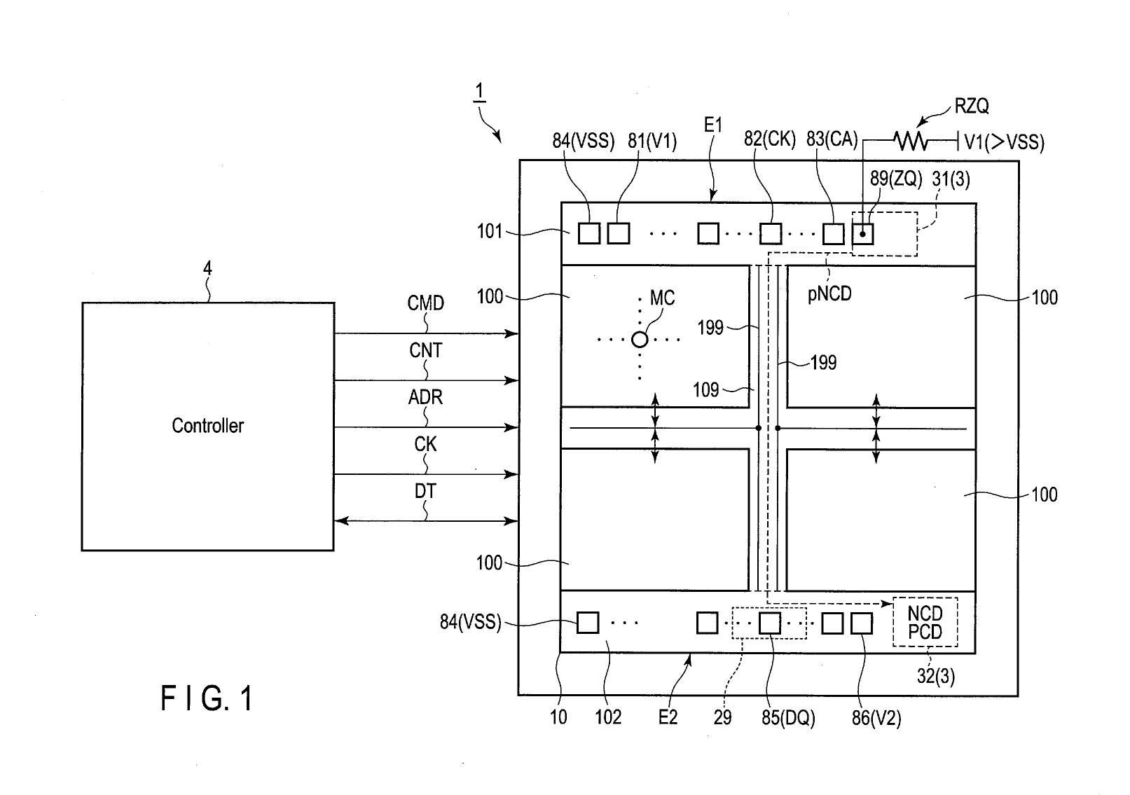

FIG. 1 to FIG. 8 are referred to for explanation of a semiconductor device of the embodiment.

(a) Whole Configuration

FIG. 1 is a schematic view to explain the semiconductor device of the present embodiment.

A semiconductor device 1 of the present embodiment is connected to a controller (a host device) 4. Any type of signal is transmitted and received between the semiconductor device 1 and the controller 4.

The controller 4 issues a command indicating a request for an operation to the semiconductor device 1. When the semiconductor device 1 is a semiconductor memory, a command CMD is, for example, a writing command or a reading command.

The controller 4 outputs, to the semiconductor memory 1, an address ADR of a data writing or data reading object.

The controller 4 supplies, to the semiconductor memory 1, a control signal CNT to control the operation of the semiconductor memory 1 together with the command CMD and the address ADR. The control signal includes a clock enabling signal, a chip selection signal and the like.

The controller 4 outputs, to the semiconductor memory 1, an external clock CK to control an operation timing of the semiconductor memory 1.

Data DT is transferred between the controller 4 and the semiconductor memory 1 in accordance with the operation indicated by the command CMD.

The semiconductor memory 1 executes the operation requested by the controller 4 on the basis of the command CMD and the control signal CNT from the controller 4.

The semiconductor memory 1 includes one or more semiconductor chips 10. The semiconductor chips 10 are covered with a package material (not shown).

The semiconductor memory 1 includes external connection terminals 81, 82, 83, 84, 85, 86, and 89 to transmit and receive the signals. The external connection terminals 81 to 86 and 89 are, for example, pads. The external connection terminals 81 to 86 and 89 may be pins or ball grids.

The pads 81 to 86 and 89 are used as part of an interface to connect the semiconductor memory 1 to the controller 4. The pads 81 to 86 and 89 are connected to the command/address lines CAs, the data lines DQs and the control signal lines in accordance with functions assigned to the pads. The command/address line CA is used for the reception of the command CMD and the address ADR. The data line DQ is used for the transmission and reception of the data. The control signal line is used for the supply of the control signal.

The pads 81 to 86 and 89 are arranged in regions (hereinafter called pad arrangement regions) 101, 102 in each of the semiconductor chips 10.

The two pad arrangement regions 101, 102 are disposed on one end side and the other end side of the semiconductor chip 10 which face each other. The pads in the first pad arrangement region 101 are arranged along a first side of the semiconductor chip 10. The pads in the second pad arrangement region 102 are arranged along a second side which faces the first side.

For example, in the first pad arrangement region 101, there are mainly disposed various pads for use in control of the memory; for example, a pad for the reception of the command/address, a CSb pad for the reception of the chip selection signal and the like. For example, in the second pad arrangement region 102, there are mainly disposed pads for the transmission/reception of the data, for example, a pad for FIFO, a pad for a data strobe signal and the like.

The semiconductor memory 1 includes the CA pads 83 for the reception of the command CMD, the control signal CNT and the address ADR. The semiconductor memory 1 includes the DQ pads 85 for the transmission and reception of the data.

For example, the CA pads 83 and the DQ pads 85 are divided on the semiconductor chip 10. The CA pads 83 are disposed in the first pad arrangement region 101 on the one end (a first end portion E1) side of the semiconductor chip 10. The DQ pads 85 are disposed in the second pad arrangement region 102 on the other end (a second end portion E2) side of the semiconductor chip 10. The second end portion E2 is opposite to the first end portion E1.

Furthermore, in the first and second pad arrangement regions 101, 102, there are disposed the pads 81, 84, and 86 to which various voltages V1, VSS and V2 are applied, respectively. The first voltage V1 is applied to the pad 81. The ground voltage VSS is applied to the pad 84. The voltage V2 is applied to the pad 85. Each of the voltages V1, V2 to be applied to the pads 81, 85 is a voltage larger than the ground voltage VSS. A power source system of the pad 81 in the first pad arrangement region 101 is different from a power source system of the pad 86 in the second pad arrangement region 102. In accordance with a specification/standard of the semiconductor memory 1, a size of the voltage V1 to be applied to the pad 81 is sometimes the same as a size of the voltage V2 to be applied to the pad 86, and sometimes different.

The pad 82 receives the external clock CK from the controller 4. The pad 82 is disposed in the vicinity of the center of the first pad arrangement region 101.

The semiconductor memory 1 includes the pad (e.g., the ZQ pad) 89 for use in processing to ensure the operation of the semiconductor memory 1. The ZQ pad 89 is a pad for use in calibration of the output impedance of an input/output circuit 29 at supply of a power source voltage of the semiconductor memory 1 (at the start-up of the semiconductor memory 1). The ZQ pad 89 has a function of a reference voltage node for the calibration of the output impedance of the input/output circuit 29. The ZQ pad 89 is disposed in the first pad arrangement region 101. For example, the ZQ pad 89 is laid out in an end part of the first pad arrangement region 101.

The semiconductor memory 1 includes a memory core including memory cells MCs, and a peripheral circuit to control an operation of each memory cell. Circuit regions 100 provided with circuits of the semiconductor memory 1 are disposed in the chip 10 of the semiconductor memory 1. The memory core and most part of the peripheral circuit are mainly disposed in each of the circuit regions 100.

The semiconductor memory 1 includes an interconnect region 109 in the chip 10. By interconnects (buses) 199 in the interconnect region 109, the respective circuits in the circuit region 100 are connected to the respective pads 81 to 89 in the pad arrangement regions 101, 102, and the respective circuits in the circuit regions 100 are connected to one another. In consequence, the input and output of any type of signal and data in the semiconductor memory 1 are executed.

For example, in the pad arrangement regions 101, 102, a part of the peripheral circuit (e.g., a buffer circuit) is disposed.

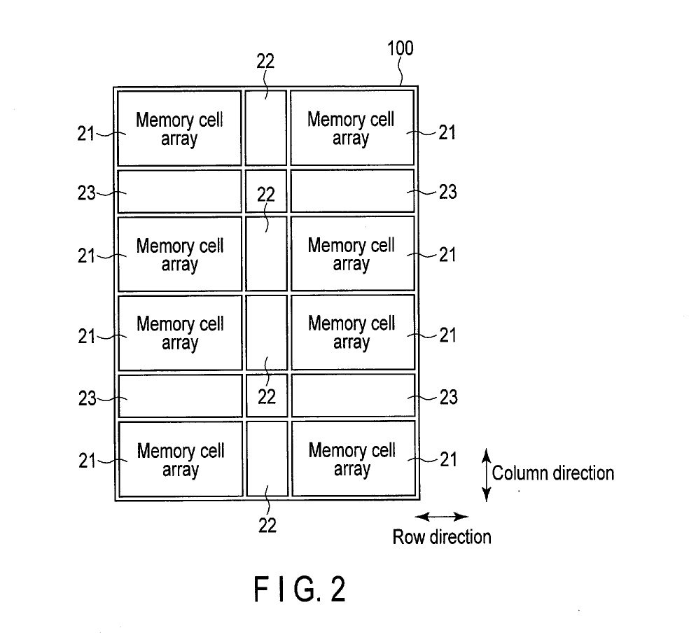

FIG. 2 is a plan view showing one example of the layout of the circuit regions of the semiconductor memory.

FIG. 2 shows the extracted memory core in the circuit region 100. The memory core includes one or more memory cell arrays 21, one or more row control circuits 22, and one or more column control circuits 23.

As shown in FIG. 2, the memory cell arrays 21 are disposed in one circuit region 100.

The row control circuits 22 and the column control circuits 23 are disposed in the circuit region 100 so as to control operations of the respective memory cell arrays 21. The row control circuits 22 are adjacent to the memory cell arrays 21 in a row direction thereof. The column control circuits 23 are adjacent to the memory cell arrays 21 in a column direction thereof.

For example, the respective circuits for use in the reading and writing of the data are disposed in the same regions as the column control circuits 23.

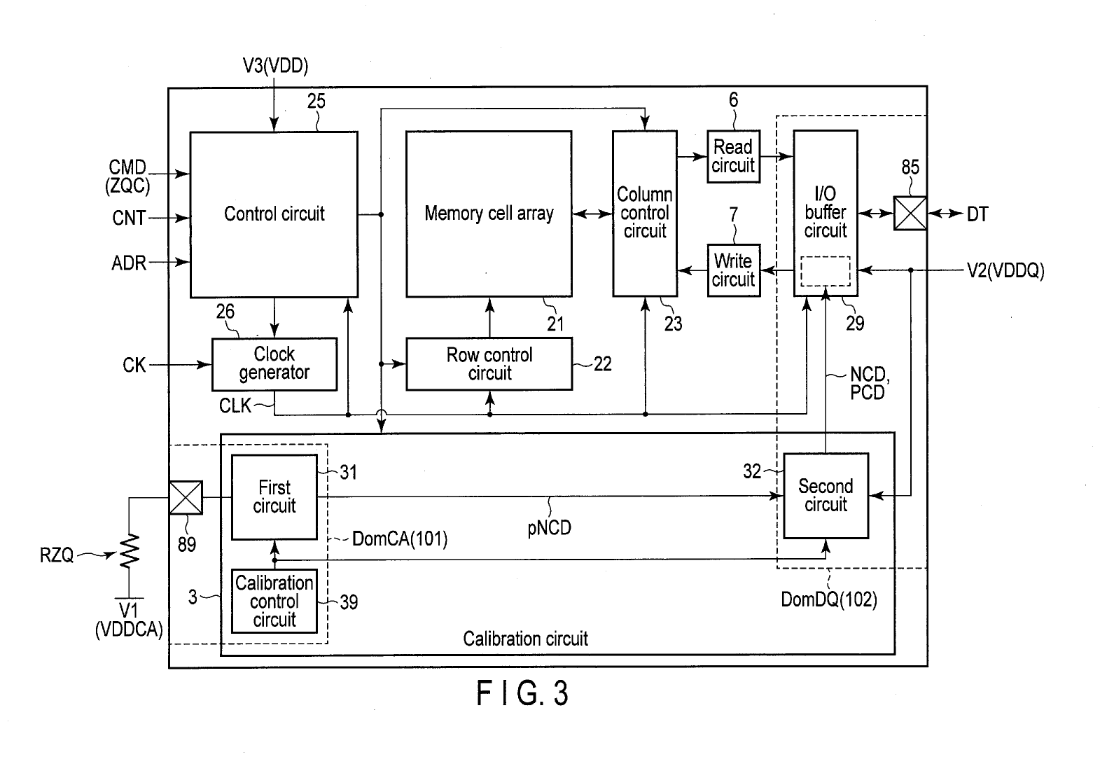

FIG. 3 is a block diagram showing a part of a circuit configuration of the semiconductor memory 1.

FIG. 3 schematically shows one memory cell array 21, one row control circuit 22 and one column control circuit 23 for simplicity of drawing.

The row control circuit 22 includes, for example, a row decoder and a row switch circuit. The row decoder decodes, for example, a row address (and a bank address) in the address ADR. The row address is a signal to select a row of the memory cell arrays 21. The switch circuit activates the row (e.g., a word line) indicated in the address ADR.

The column control circuit 23 includes, for example, a column decoder and a column switch circuit. The column decoder decodes, for example, a column address in the address ADR. The column address is a signal to select a column (a bit line) in the memory cell array 21. For example, the column switch circuit activates the column (e.g., the bit line) indicated in the address ADR.

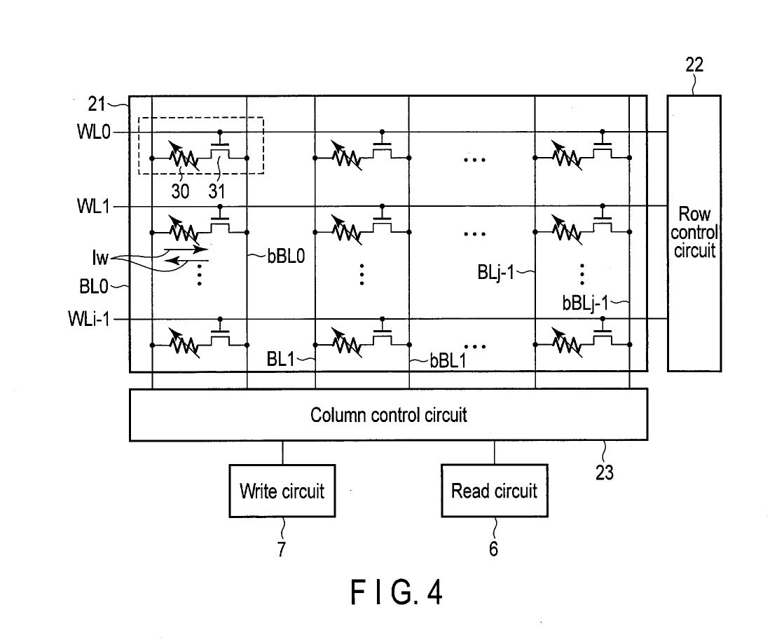

FIG. 4 is a view showing a configuration example of the memory cell array.

As shown in FIG. 4, the memory cells MCs are arranged in the form of a matrix in the memory cell array 21.

Word lines WL0 to WLi-1 and bit lines BL0 to BLj-1, bBL0 to bBLj-1 are disposed in a bank BK. In the following description, when the respective word lines WL0 to WLi-1 are not distinguished, each word line is written as a word line WL. When the respective bit lines BL0 to BLj-1 are not distinguished, each bit line is written as a bit line BL. When the respective bit lines (source lines) bBL0 to bBLj-1 are not distinguished, each bit line is written as a bit line bBL.

The memory cell MC is connected between the bit lines BL and bBL. The activation of the memory cell MC is controlled by the word line WL.

The memory cells MCs arranged in the column direction are connected to a common pair of bit lines BL, bBL. The memory cells MCs arranged in the row direction are connected to the common word line WL.

The memory cell array 21 may have an internal configuration of a hierarchical bit line system and a hierarchical word line system.

For example, the semiconductor memory 1 of the present embodiment is a spin transfer torque type magnetoresistive random access memory (STT-MRAM).

A memory element 90 of the MRAM 1 is a magnetoresistive effect element.

The memory cell MC includes, for example, one magnetoresistive effect element 90 as the memory element, and one selection switch 91.

The magnetoresistive effect element 90 is, for example, a magnetic tunnel junction (MTJ) element 90.

The selection switch 91 is, for example, a field effect transistor. In the following, the field effect transistor as the selection switch 91 will be called a select transistor (or a cell transistor) 91.

One end of the MTJ element 90 is connected to the bit line BL, and the other end of the MTJ element 90 is connected to one end (source/drain) of a current path of the select transistor 91. The other end (drain/source) of the current path of the select transistor 91 is connected to the bit line bBL. A control terminal (gate) of the select transistor 91 is connected to the word line WL.

The word line WL is connected to the row control circuit 22. The bit lines BL, bBL are connected to the column control circuit 23.

When the semiconductor memory 1 is an MRAM, the semiconductor memory 1 includes a reading circuit 6 and a writing circuit 7. For example, the reading circuit 6 and the writing circuit 7 are connected to the column control circuit 23.

The reading circuit 6 and the writing circuit 7 supply a current (or a voltage) to read the data or write the data, to the memory cell MC in the memory cell array 21 via the column control circuit 23.

The reading circuit 6 is connected to the bit lines BL, bBL via the column control circuit 23. The reading circuit 6 includes a sense amplifier which performs sensing and amplification of a signal (a reading signal) on the bit lines BL, bBL, a latch (a flip flop) which temporarily holds the reading signal, and the like. The reading circuit 6 supplies the reading current to the selected cell during the reading of the data from the MTJ element 90. The reading circuit 6 senses a variance amount of a current/potential of the bit line (the reading signal, reading output) corresponding to a size of a resistance value of the MTJ element 90, and distinguishes the data stored in the MTJ element 90.

In the STT-MRAM 1, the writing circuit 7 generates the writing current to change a magnetic resistance (the resistance value) of the MTJ element 90, and supplies the writing current to the memory cell MC.

The writing circuit 7 allows a writing current 1w, which flows in a direction in accordance with the data to be written into the selected cell, to flow into the MTJ element 90 of the memory cell MC during the writing of the data into the MTJ element 90. The writing circuit 7 outputs the writing current from the bit line BL toward the bit line bBL or the writing current from the bit line bBL toward the bit line BL in accordance with the data to be written into the MTJ element 90.

In accordance with the chip layout of the semiconductor memory 1, the column control circuits 23, the reading circuits 6 and the writing circuits 7 may be disposed on both of the one end side and the other end side of the memory cell array 21 in the column direction.

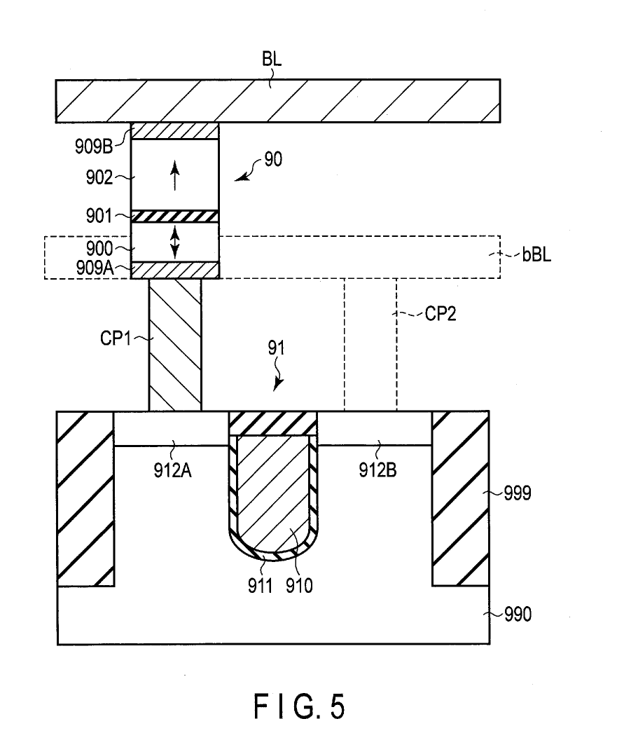

FIG. 5 is a sectional view schematically showing a configuration example of the memory cell MC. FIG. 5 shows, by broken lines, members disposed in a depth direction (or a front direction) of the drawing.

The memory cell MC is formed in an active region (a semiconductor region) of a semiconductor substrate 990 (the semiconductor chip 10). The active region is defined by an insulation film 999 buried in an element isolating region of the semiconductor substrate 990.

The surface of the semiconductor substrate 990 is covered with an interlayer insulation film (not shown).

The MTJ element 90 is disposed in the interlayer insulation film. The MTJ element 90 includes at least a storage layer (also called a recording layer or a magnetization free layer) 900, a reference layer (also called a pin layer, a pinned layer, or a magnetization unchangeable layer) 902, and a nonmagnetic layer (a tunnel barrier layer) 901 between the storage layer 900 and the reference layer 902.

A direction of the magnetization of the storage layer 900 changes in accordance with a spin torque of the writing current Iw. The direction of the magnetization of the reference layer 902 does not change in accordance with the writing current Iw. By the supply of the writing current Iw, a relative magnetization arrangement of the two magnetic layers 900, 902 changes between a parallel arrangement state and an antiparallel arrangement state, and the resistance value (the magnetic resistance) of the MTJ element 90 changes.

The select transistor 91 is a field effect transistor of a buried gate structure.

A gate electrode 910 is buried in the active region (the substrate 990) between two source/drain diffusion layers 912A and 912B. A gate insulation film 911 is interposed between the gate electrode 910 and the active region. The gate electrode 910 extends in the row direction and is used as the word line WL.

The select transistor 91 may be a field effect transistor of a planar structure, or a FinFET.

An upper end of the MTJ element 90 is connected to the bit line BL via an upper electrode 909B. Furthermore, a lower end of the MTJ element 90 is connected to the source/drain diffusion layer 912A of the select transistor 91 via a lower electrode 909A and a contact plug CP1. The source/drain diffusion layer 912B of the select transistor 91 is connected to the bit line bBL via a contact plug CP2 disposed in the depth direction (or the front direction) in the drawing.

As shown in FIG. 3, the MRAM 1 includes a control circuit 25, a clock generator 26, the input/output circuit 29, and a calibration circuit 3, in addition to the memory core.

The control circuit 25 controls an internal operation of the semiconductor memory 1 on the basis of the command CMD, the control signal CNT and the address ADR from the controller 4.

The clock generator 26 generates an internal clock CLK in the MRAM 1 on the basis of the external clock CK from the controller 4. The internal clock CLK is supplied to the respective circuits 22, 23, 25 and 29 of the semiconductor memory 1. Each of the circuits 22, 23, 25 and 29 in the semiconductor memory 1 drives at an operation timing based on the internal clock CLK.

The input/output circuit 29 includes input buffer circuits (not shown) and output buffer circuits 290. For example, each of the number of the input buffer circuits and the number of the output buffer circuits 290 is, for example, the number of byte units. Each input buffer circuit receives the data DT from the controller 4 via the data line (the DQ line) and the DQ pad 85. Each of the output buffer circuits 290 transmits the data DT from the memory cell array 21 to the controller 4 via the DQ pad 85 and the data line. A circuit of the last stage in the output buffer circuit 290 is also called a driver circuit.

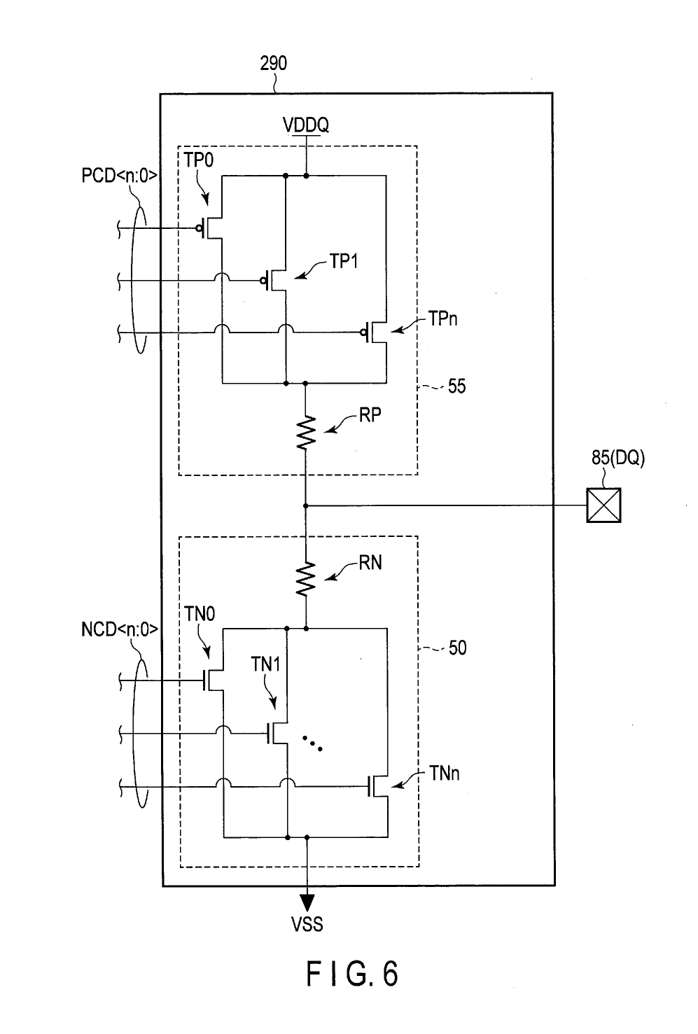

FIG. 6 is a view showing one example of an internal configuration of the output buffer circuit (the driver circuit).

The output buffer circuit 290 includes a pull-down circuit 50 and a pull-up circuit 55.

The pull-down circuit 50 includes N-channel type field effect transistors (hereinafter written as N-type transistors) TN0, TN1, . . . TNn, and a resistance element RN.

The number of the N-type transistors TN0, TN1, . . . TNn is n+1. The N-type transistors TN0, TN1, . . . TNn have gate widths and gate lengths of sizes different from one another (ratios between the gate widths and the gate lengths), respectively.

The N-type transistors TN0, TN1, . . . TNn are connected in parallel. Ends of the respective N-type transistors TN0, TN1, . . . TNn are connected to one another, and the other ends of the respective N-type transistors TN0, TN1, . . . TNn are connected to one another.

One end of each of the N-type transistors TN0, TN1, . . . TNn is connected to one end of the resistance element RN. The other end of each of the N-type transistors TN0, TN1, . . . TNn is connected to the terminal to which the ground voltage VSS is applied.

In the following, when the respective N-type transistors TN0, TN1, . . . TNn are not distinguished, these N-type transistors will be written as the N-type transistors TN.

The pull-up circuit 55 includes P-channel type field effect transistors (hereinafter written as P-type transistors) TP0, TP1, TPn, and a resistance element RP.

The number of the P-type transistors TP0, TP1, . . . TPn is the same as the number of the N-type transistors TN0, TN1, . . . TNn. The P-type transistors TP0, TP1, . . . TPn have gate widths and gate lengths of sizes different from one another (ratios between the gate widths and the gate lengths), respectively.

The P-type transistors TP0, TP1, . . . TPn are connected in parallel. Ends of the respective P-type transistors TP0, TP1, . . . TPn are connected to one another, and the other ends of the respective P-type transistors TP0, TP1, . . . TPn are connected to one another.

One end of each of the P-type transistors TP0, TP1, TPn is connected to a power source terminal V2. The other end of each of the P-type transistors TP0, TP1, . . . TPn is connected to one end of the resistance element RP.

In the following, when the respective P-type transistors TP0, TP1, . . . TPn are not distinguished, these P-type transistors will be written as the P-type transistors TP.

The other end of the resistance element RP of the pull-up circuit 55 is connected to the other end of the resistance element RN of the pull-down circuit 50.

A connection node between the pull-up circuit 55 and the pull-down circuit 50 is an output node of the output buffer circuit 290. The output node of the output buffer circuit 290 is connected to the DQ pad 85.

A control code (a control signal) NCD<n:0> is supplied to a gate of each N-type transistor TN of the pull-down circuit 50. A control code PCD<n:0> is supplied to a gate of each P-type transistor TP of the pull-up circuit 55.

The control codes NCD<n:0>, PCD<n:0> are control signals to control the impedance of the output buffer circuit 290 connected to the DQ pad (the data line). For example, each of the control codes NCD<n:0>, PCD<n:0> is an n+1 bit signal. A signal of 1 bit (H level/L level) in the control codes NCD<n:0>, PCD<n:0> indicates an on/off state of one transistor.

The on/off states of the N-type transistor TN and the P-type transistor TP are controlled on the basis of the control codes NCD<n:0>, PCD<n:0>, with the result that outputs (drive abilities) of the pull-down circuit 50 and the pull-up circuit 55 change. The outputs of the pull-down circuit 50 and the pull-up circuit 55 are controlled, and the impedance of the output buffer circuit (the driver circuit) 290 is thereby regulated. As a result, the impedance of the DQ pad 85 is set to a value close to a predetermined resistance value (e.g., 240Ω) based on the standard or specification of the memory. For example, when a stipulated impedance of the DQ pad 85 is 240Ω, each of the resistance elements RN, RP has a resistance value of about 120 Ω.

In the following, the respective control codes NCD<n:0>, PCD<n:0> will also be written as the codes NCD, PCD.

For example, the output buffer circuit 290 is driven by the voltage V2 of the pad 86 disposed in the second pad arrangement region 102. In the JEDEC memory standard, the power source voltage V2 on the side of the pad arrangement region 102 where the DQ pad is disposed is written as VDDQ, and the power source voltage V1 on the side of the pad arrangement region 101 where the CA pad 83 is disposed is written as VDDCA.

In the following, a region (and a circuit) of a power source system of the voltage VDDCA (V1) will be called a VDDCA domain DomCA, and a region (and a circuit) of a power source system of the voltage VDDQ (V2) will be called a VDDQ domain DomDQ.

The circuits disposed in the circuit region 100 and the interconnect region 199, for example, the memory cell array 21, the row/column control circuits 22, 23, the control circuit 25 and the like belong to a power source system different from the power source systems of the power source voltage VDDCA, VDDQ, and a voltage V3 is supplied to the circuits 22, 23, and 25. The voltage V3 is written as the power source voltage VDD.

For example, the voltage VDDCA is about 1.2 V and the voltage VDDQ is about 1.2 V. For example, the voltage VDD is about 1.2 V. Additionally, in accordance with the specification and standard of the semiconductor memory and type of memory, the voltage VDDCA, VDDQ or VDD is a voltage larger than 1.2 V (e.g., from 1.5 V to 1.8 V) sometimes, or a voltage smaller than 1.2 V (e.g., from 0.8 V to 1.0 V) sometimes. The size of the voltage VDDCA is different from the size of the voltage VDDQ sometimes.

In the following, a terminal to supply the power source voltage VDDCA to the circuit and element will be written as the power source terminal (or the voltage terminal) VDDCA, and a terminal to supply the power source voltage VDDQ to the circuit and element will be written as the power source terminal (or the voltage terminal) VDDQ. A terminal to supply the ground voltage VSS to the circuit and element will be written as a ground terminal VSS.

The MRAM 1 of the present embodiment includes the calibration circuit 3.

There is the possibility that an output impedance of the semiconductor memory (the semiconductor device) fluctuates in accordance with process conditions during manufacturing. Furthermore, there is the possibility that the output impedance of the semiconductor memory varies depending on the power source voltage or an ambient temperature during actual use. Therefore, when a deviation of the output impedance from a standard value is preferably small for a high speed operation of the memory or improvement of a quality of the signal, the calibration circuit (hereinafter called the ZQ calibration circuit) 3 is disposed in the semiconductor memory 1 for correction (called the ZQ calibration) of the output impedance.

The ZQ calibration circuit 3 executes an operation for the correction of the output impedance within a predetermined period from application of the power source voltages VDDCA, VDDQ (the start of the semiconductor memory) on the basis of a command ZQC from the outside by use of, for example, a resistance value of a resistance element RZQ connected to the ZQ pad 89 as a reference. For example, the resistance element RZQ is disposed on the outside of the semiconductor chip 10 (e.g., on a circuit board). However, the resistance element RZQ may be disposed in the same package as in the semiconductor chip 10.

The ZQ calibration circuit 3 generates the control codes (hereinafter also called calibration codes) NCD, PCD and regulates the impedance of the output buffer circuit 290.

By a calibration operation of the ZQ calibration circuit 3, the output impedance of the output buffer circuit 290 is regulated so as to match an impedance of a transmission line.

It is to be noted that the calibration operation of the output impedance by the ZQ calibration circuit 3 may be executed in a predetermined cycle during the actual use of the semiconductor memory 1.

In the MRAM 1 of the present embodiment, the ZQ calibration circuit 3 is divided into two stages 31, 32 corresponding to the two power source voltage regions (domains) DomCA, DomDQ.

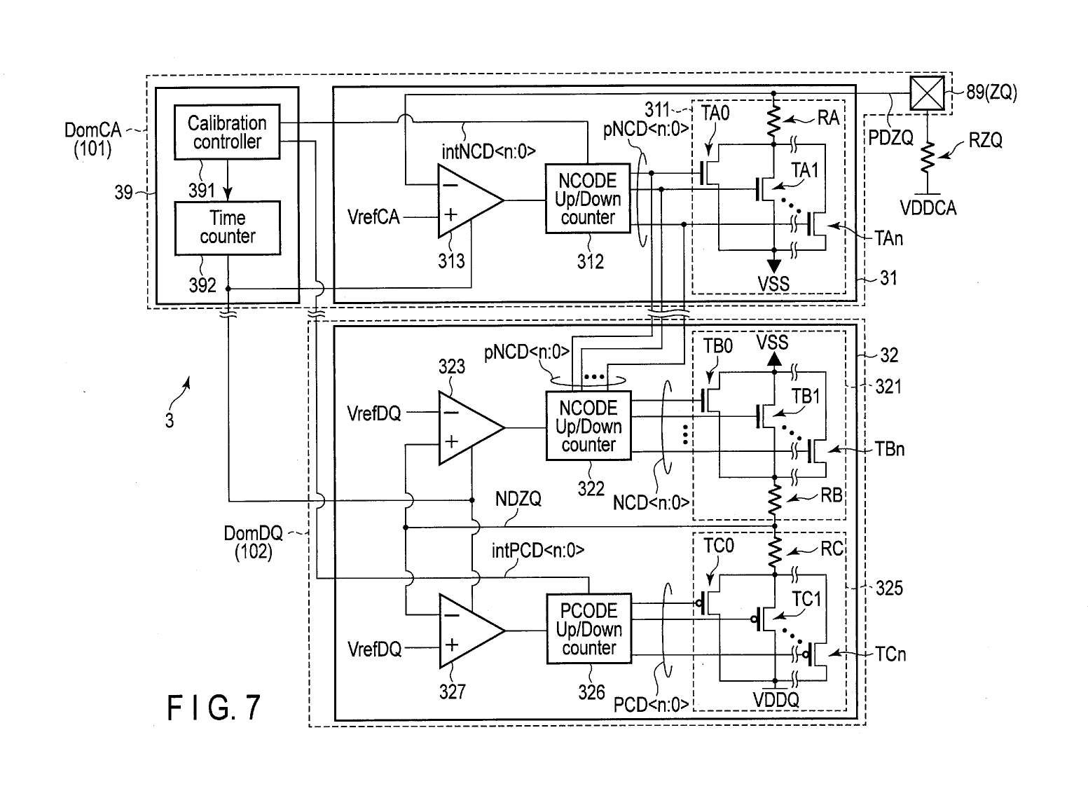

FIG. 7 is a circuit diagram showing a configuration example of the ZQ calibration circuit in the MRAM of the present embodiment.

The ZQ calibration circuit 3 of the present embodiment is connected to the resistance element RZQ via the ZQ pad 89.

The resistance element (the external resistance element) RZQ is connected between the ZQ pad 89 of the VDDCA domain DomCA (the first pad arrangement region 101) and the power source voltage terminal VDDCA. The resistance element RZQ is a resistance element to ensure the operation of the semiconductor memory, and a reference resistor to regulate the output impedance of the semiconductor memory 1. When the semiconductor memory is driven on the basis of the JEDEC memory standard (e.g., LPDDR standard), the resistance value of the resistance element RZQ is, for example, about 240Ω. However, the resistance value of the resistance element RZQ may be 120 Ω, 80Ω or 40Ω in accordance with the specification/standard of the output impedance of the semiconductor memory.

In the semiconductor memory of the present embodiment, the power source voltage VDDCA is applied to the resistance element RZQ. The ZQ pad 89 is connected to a terminal (e.g., an external terminal) to which the voltage VDDCA larger than the ground voltage VSS is applied, via the resistance element RZQ. In consequence, the voltage larger than the ground voltage VSS is applied to the ZQ pad 89 from the outside of the semiconductor chip 10 via the external resistance element RZQ. As a reference voltage of the ZQ pad 89, the voltage larger than the ground voltage VSS is used.

In the present embodiment, the ZQ calibration circuit 3 includes a first calibration code generation circuit (a first circuit) 31, a second calibration code generation circuit (a second circuit) 32, and a calibration control circuit 39.

The first calibration code generation circuit 31 includes a first replica circuit 311, a first comparison circuit 313, and a first counter circuit 312.

The first replica circuit 311 is connected between a node PDZQ connected to the ZQ pad 89 and the ground terminal VSS.

The first replica circuit (a pull-down replica circuit) 311 has substantially the same configuration as in the pull-down circuit 50 of the output buffer circuit 290. The first replica circuit 311 includes N-type transistors TA0, TA1, TAn, and a resistance element RA.

The N-type transistors TA0, TA1, TAn are connected in parallel.

One end of a current path of each of the N-type transistors TA0, TA1, TAn is connected to the node PDZQ of the ZQ pad 89 via one end of the resistance element RA. The other end of each of the N-type transistors TA0, TA1, TAn is connected to the ground terminal VSS.

The number of the N-type transistors TA0, TA1, TAn is the same as the number (n+1) of the N-type transistors TNS in the output buffer circuit 290. The N-type transistors TA0, TA1, TAn have gate widths and gate lengths of sizes different from one another (ratios between the gate widths and the gate lengths), respectively. In the following, when the N-type transistors TA0, TA1, TAn are not distinguished, these N-type transistors will be written as N-type transistors TA.

The resistance element RA has substantially the same resistance value as the resistance value of the resistance element RN of the pull-down circuit 50 of the output buffer circuit 290. The size of the resistance value of the resistance element RA is half that of the resistance value of the external resistance element (a reference resistance element), and is, for example, about 120 Ω.

A voltage larger than the ground voltage VSS is applied to one end of the first replica circuit 311 (a terminal on the side of the node PDZQ) via the ZQ pad 89. The ground voltage VSS is applied to the other end of the replica circuit 311.

The first comparison circuit 313 includes two input terminals, one output terminal, and one control terminal.

One input terminal of the first comparison circuit 313 is connected to the node PDZQ of the ZQ pad 89, in common with one end of the first replica circuit 311. A voltage of the node PDZQ (a voltage of the ZQ pad 89) is supplied to the one input terminal of the first comparison circuit 313.

A reference voltage VrefCA is supplied to the other input terminal of the first comparison circuit 313. For example, the reference voltage VrefCA is set to a level of about half of the voltage VDDCA.

The output terminal of the first comparison circuit 313 is connected to the first counter circuit 312.

The first comparison circuit 313 compares the voltage (the potential) of the node PDZQ with the reference voltage VrefCA. In accordance with the comparison result of the first comparison circuit 313, the first comparison circuit 313 outputs a signal of H level or L level.

The first counter circuit 312 is interposed between the first replica circuit 311 and the first comparison circuit 313.

An input terminal of the first counter circuit 312 is connected to the output terminal of the first comparison circuit 313. Output terminals of the first counter circuit 312 are connected to control terminals of the first replica circuit 311 (gates of the N-type transistors TA), respectively.

The output signal (the comparison result) of the first comparison circuit 313 and an initial code intNCD<n:0> are supplied to the first counter circuit 312. The first counter circuit 312 generates and updates a pre-calibration code pNCD<n:0> by use of the output signal (the signal of the H/L level) of the first comparison circuit 313 and the initial code intNCD<n:0>. The first counter circuit 312 is an up/down counter which can execute at least one of a count-up operation (increment processing) and a count-down operation (decrement processing) to the code pNCD<n:0>.

The first counter circuit 312 supplies the updated pre-calibration code pNCD<n:0> to the first replica circuit 311.

On/off states of the N-type transistors TA are controlled on the basis of the pre-calibration code pNCD<n:0>. The pre-calibration code pNCD<n:0> is a signal of a bit number (here, n+1 bit) corresponding to the number of the N-type transistors TA. The pre-calibration code pNCD<n:0> is also written as the pre-calibration code pNCD, for simplicity of the description.

One of n+1 cord lines as the output terminals of the first counter circuit 312 is connected to the gate of one N-type transistor TA among the n+1 N-type transistors TA, and the 1-bit signal included in the pre-calibration code pNCD is supplied to the gate of each N-type transistor TA.

By feedback processing in the first calibration code generation circuit 31, there is generated the pre-calibration code pNCD to control the on/off states of the transistor TA and transistors in a circuit of the subsequent stage. The pre-calibration code pNCD is determined on the basis of the comparison result of the voltage to be applied to the ZQ pad 89 with the reference voltage VrefCA, and transferred to the second calibration code generation circuit 32.

It is to be noted that the first calibration code generation circuit 31 and the second calibration code generation circuit 32 are disposed in the domains DomCA, DomDQ divided from each other, which causes the possibility that a length of an interconnect to transfer the pre-calibration code pNCD lengthens. However, the pre-calibration code pNCD is a logic signal (a signal of the H/L level), and hence an influence of deterioration of the signal caused by the increase of the interconnect length is smaller as compared with an influence of a drop of the power source voltage.

In this way, one or more N-type transistors TA to be driven is selected from the N-type transistors TA having different gate sizes on the basis of the comparison result of the voltage of the node PDZQ of the ZQ pad with the reference voltage VrefCA, and the size of an impedance (a drive ability) of the first replica circuit 311 is thereby controlled.

The first calibration code generation circuit 31 is driven in the VDDCA domain DomCA on the basis of the voltage VDDCA and the ground voltage VSS. For example, the first calibration code generation circuit 31 is controlled so that the voltage (the potential) of the node PDZQ is about a half of the voltage VDDCA.

The second calibration code generation circuit 32 includes a second replica circuit 321, a third replica circuit 325, a second comparison circuit 323, a third comparison circuit 327, a second counter circuit 322, and a third counter circuit 326.

The second replica circuit (a pull-down replica circuit) 321 has a circuit configuration similar to the pull-down circuit 50 of the output buffer circuit 290.

The second replica circuit 321 includes N-type transistors TB0, TB1, TBn, and a resistance element RB.

The N-type transistors TB0, TB1, TBn are connected in parallel.

One end of a current path of each of the N-type transistors TB0, TB1, TBn is connected to one end of the resistance element RB. The other end of a current path of each of the N-type transistors TB0, TB1, TBn is connected to a terminal of the ground voltage VSS. The other end of the resistance element RB is connected to a node NDZQ.

The N-type transistors TB0, TB1, TBn have gate widths and gate lengths of sizes different from one another (or ratios between the gate widths and the gate lengths), respectively. In the following, when the N-type transistors TB0, TB1, TBn are not distinguished, these N-type transistors will be written as N-type transistors TB.

The resistance element RB has substantially the same resistance value as the resistance value of the resistance element RN of the pull-down circuit 50 of the output buffer circuit 290. The resistance value of the resistance element RB is about half of the value of the reference resistance element RZQ, and is, for example, about 120 Ω.

The second replica circuit 321 has substantially the same internal configuration as the first replica circuit 311. Additionally, the voltage region DomDQ where the second replica circuit 321 is disposed is separated from the voltage region DomCA where the first replica circuit 311 is disposed. Therefore, the second replica circuit 321 in the vicinity of the output buffer circuit 290 can regulate the calibration code pNCD of the pull-down circuit based on the voltage VDDCA (and a fluctuation of manufacturing on a first domain side) into the calibration code NCD based on the voltage VDDQ (a fluctuation of manufacturing on a second domain side).

The third replica circuit (a pull-up replica circuit) 325 has a circuit configuration similar to the pull-up circuit 55 of the output buffer circuit 290.

The third replica circuit 325 includes P-type transistors TC0, TC1, . . . TCn, and a resistance element RC.

The P-type transistors TC0, TC1, . . . TCn are connected in parallel.

One end of a current path of each of the P-type transistors TC0, TC1, . . . TCn is connected to a voltage terminal of the voltage VDDQ. The other end of a current path of each of the P-type transistors TC0, TC1, . . . TCn is connected to one end of the resistance element RC. The other end of the resistance element RC is connected to the node NDZQ.

The P-type transistors TC0, TC1, . . . TCn have gate widths and gate lengths of sizes different from one another (ratios between the gate widths and the gate lengths), respectively. In the following, when the P-type transistors TC0, TC1, . . . TCn are not distinguished, these P-type transistors will be written as P-type transistors TC.

The resistance element RC has substantially the same resistance value as the resistance value of the resistance element RP of the pull-up circuit 55 of the output buffer circuit 290. The resistance value of the resistance element RC is about half of the value of the reference resistance element RZQ, and is, for example, about 120 Ω.

The other end of the resistance element RC of the third replica circuit (pull-up replica circuit) 325 is connected to the other end of the resistance element RB of the second replica circuit 321 via the node NDZQ.

In this way, a configuration including the second replica circuit 321 and the third replica circuit 325 is similar to the circuit configuration of the output buffer circuit 290.

The second comparison circuit 323 includes two input terminals, one output terminal, and one control terminal.

One input terminal of the second comparison circuit 323 is connected to the node NDZQ. A voltage (a potential) of the node NDZQ is supplied to the one input terminal of the second comparison circuit 323. A reference voltage VrefDQ is applied to the other input terminal of the second comparison circuit 323.

The third comparison circuit 327 includes two input terminals, one output terminal, and one control terminal.

One input terminal of the third comparison circuit 327 is connected to the node NDZQ. A voltage of the node NDZQ is applied to the one input terminal of the third comparison circuit 327. The reference voltage VrefDQ is applied to the other input terminal of the third comparison circuit 327.

The voltages to be supplied to the second and third comparison circuits 323, 327 are about the same. The second and third comparison circuits 323, 327 output signals (comparison results) of substantially the same size. The second and third comparison circuits 323, 327 compare the voltage of the node NDZQ with the reference voltage VrefDQ, and output a signal of an H level or L level in accordance with the comparison result. The reference voltage VrefDQ is about half of the voltage VDDQ.

The second counter circuit 322 is interposed between the second replica circuit 321 and the second comparison circuit 323. An input terminal of the second counter circuit 322 is connected to the output terminal of the second comparison circuit 323. Output terminals of the second counter circuit 322 are connected to control terminals of the second replica circuit 321 (gates of the N-type transistors TB), respectively.

The pre-calibration code pNCD<n:0> from the first calibration code generation circuit 31 is supplied to the second counter circuit 322.

The second counter circuit 322 generates and updates the calibration code NCD<n:0> on the basis of the pre calibration code pNCD<n:0> and the output signal (the comparison result) of the second comparison circuit 323. On the basis of the comparison result (the signal of the H/L level) of the second comparison circuit 323, the second counter circuit 322 executes count processing to the pre-calibration code pNCD as an initial value, and generates and updates the calibration code NCD<n:0>. The second counter circuit 322 is, for example, an up/down counter. A count operation of the counter circuit 322 is at least one of the count-up operation (increment processing) and the count-down operation (decrement processing).

The second counter circuit 322 supplies the calibration code NCD<n:0> to the second replica circuit 321.

On/off states of the N-type transistors TB are controlled on the basis of the calibration code NCD<n:0>. The calibration code NCD<n:0> is a signal of a bit number (here, n+1 bit) corresponding to the number of the N-type transistors TB.

One of n+1 cord lines as the output terminals of the second counter circuit 322 is connected to the gate of one N-type transistor TB among the n+1 N-type transistors TB, respectively. The 1-bit signal of the calibration code NCD is supplied to the gate of each N-type transistor TB.

On the basis of the calibration code NCD<n:0>, one or more N-type transistors TB to be driven are selected from the N-type transistors TB having different gate sizes, and a size of an impedance of the second replica circuit 321 is thereby controlled.

The third counter circuit 326 is interposed between the third replica circuit 325 and the third comparison circuit 327. An input terminal of the third counter circuit 326 is connected to the output terminal of the third comparison circuit 327. Output terminals of the third counter circuit 326 are connected to the control terminals of the third replica circuit 325 (gates of the P-type transistors TC), respectively.

The third counter circuit 326 generates and updates the calibration code PCD<n:0> by use of the output signal of the third comparison circuit 327 and an initial code intPCD<n:0>. On the basis of the comparison result (the signal of the H/L level) of the third comparison circuit 327, the third counter circuit 326 executes count processing to the initial code intPCD<n:0>, and generates and updates the calibration code PCD<n:0>.

The third counter circuit 326 is, for example, an up/down counter. The count processing of the counter circuit 326 is at least one of count-up processing (increment processing) and count-down processing (decrement processing).

The third counter circuit 326 supplies the calibration code PCD<n:0> to the third replica circuit 325.

On/off states of the P-type transistors TC are controlled on the basis of the calibration code PCD<n:0>. The calibration code PCD<n:0> is a signal of a bit number (here, n+1 bit) corresponding to the number of the P-type transistors TC, respectively.

One of n+1 cord lines as the output terminals of the third counter circuit 326 is connected to the gate of one P-type transistor TC among the n+1 P-type transistors TC. The 1-bit signal is supplied to the gate of each P-type transistor TC.

On the basis of the calibration code PCD<n:0>, one or more P-type transistors TC to be driven are selected from the P-type transistors TC having different gate sizes, and a size of an impedance of the third replica circuit 325 is thereby controlled.

When the voltage of the ZQ node NDZQ is substantially the same size as the reference voltage VrefDQ, each of the replica circuits 321, 325 has an impedance (a drive ability) of a predetermined value (here, 120Ω).

Therefore, the calibration codes NCD, PCD indicating the numbers and combinations of the transistors TB, TC in the on-state when the impedances of the replica circuits 321, 325 have the predetermined values are used as the calibration codes (the control codes) to regulate the impedances of the pull-down circuit 50 and the pull-up circuit 55 of the output buffer circuit 290.

The calibration codes NCD, PCD determined by the feedback processing of the second calibration code generation circuit 32 are transferred to the output buffer circuit 290.

The second calibration code generation circuit 32 is driven in the VDDQ domain DomDQ on the basis of the voltage VDDQ and the ground voltage VSS. For example, the second calibration code generation circuit 32 is controlled so that the voltage (the potential) of the node NDZQ is about a half of the voltage VDDQ.

For example, the number of the replica circuits 311, 321 or 325 is set to the number of byte units in accordance with the number of the output buffer circuits 290.

The calibration control circuit 39 controls the operations of the first and second calibration code generation circuits 31, 32 on the basis of the calibration command ZQC received by the control circuit 25. The calibration control circuit 39 includes a calibration controller 391 and a time counter 392.

The calibration controller 391 supplies the initial code intNCD<n:0> to the first counter circuit 312 of the first calibration code generation circuit 31. The calibration controller 391 supplies the initial code intPCD<n:0> to the third counter circuit 326 of the second calibration code generation circuit 32. It is to be noted that the initial codes intNCD<n:0>, intPCD<n:0> to the respective calibration code generation circuits 31, 32 are values preset by a test step of the MRAM, or the like. The value of the initial code intNCD<n:0> is sometimes different from the value of the initial code intPCD<n:0>, or sometimes the same.

The calibration controller 391 controls an operation of the time counter 392.

The time counter 392 controls a calibration time. The time counter 392 is connected to the control terminals of the comparison circuits 313, 323, and 327, and supplies control signals to the comparison circuits 313, 323, and 327. Comparing operations of the comparison circuits 313, 323 and 327 are synchronized with the count operation of the time counter 392. In consequence, a period to determine the calibration code by the calibration operation is controlled so as to settle in a predetermined operation period (a calibration period).

The calibration control circuit 39 may be driven on the basis of the voltage VDDCA or driven on the basis of the voltage VDDQ.

As described above, the N-type transistor TN and the P-type transistor TP of the output buffer circuit 290 are driven in accordance with the calibration codes NCD, PCD determined by the ZQ calibration circuit 3. In consequence, the output impedance of the output buffer circuit 290 is regulated to a closed value to the impedance based on the standard in accordance with an operation environment of the MRAM.

For example, the calibration codes NCD, PCD determined by the calibration circuit 3 are held in the control circuit 25 of the MRAM 1, a latch circuit (not shown) for the control in the input/output circuit 29, or a latch circuit (not shown) in the calibration circuit 3.

In the MRAM 1 of the present embodiment, the circuits 31, 32 in the calibration circuit 3 are divided into two stages. The circuits 31, 32 in the calibration circuit 3 are disposed on the sides of the mutually different regions DomCA, DomDQ in the semiconductor chip 10.

The first calibration code generation circuit 31 is disposed together with the ZQ pad 89 on the side of the VDDCA domain DomCA which belongs to the power source system of the voltage VDDCA.

The voltage VDDCA larger than the ground voltage is applied to the ZQ pad 89 via the resistance element RZQ. The voltage VDDCA is used as one of reference voltages for the ZQ calibration by the first calibration code generation circuit 31.

The second calibration code generation circuit 32 is disposed together with the DQ pad 85 and the input/output circuit 29 in the VDDQ domain DomDQ which belongs to the power source system of the voltage VDDQ.

The second calibration code generation circuit 32 substantially generates and determines the calibration codes NCD, PCD of the output buffer circuit (the output driver circuit) 290 based on the voltage VDDQ.

In consequence, for the MRAM 1 of the present embodiment, the impedance of the output buffer circuit 290 can be regulated in accordance with the calibration codes NCD, PCD of the calibration circuit 3 driven under about the same operation environment as in the output buffer circuit 290, by use of the calibration circuit 3 formed under about the same manufacturing conditions as for the output buffer circuit 290.

Consequently, in the present embodiment, the circuit 32 disposed in the vicinity of the output buffer circuit 290 is used to determine the calibration codes NCD, PCD of the output buffer circuit 290. In consequence, for the MRAM of the present embodiment, an accuracy of the calibration of the impedance of the output buffer circuit 290 can be improved by the ZQ calibration.

Therefore, for the semiconductor device of the present embodiment, a reliability of the operation of the circuit can be improved.

### (b) Operation Example

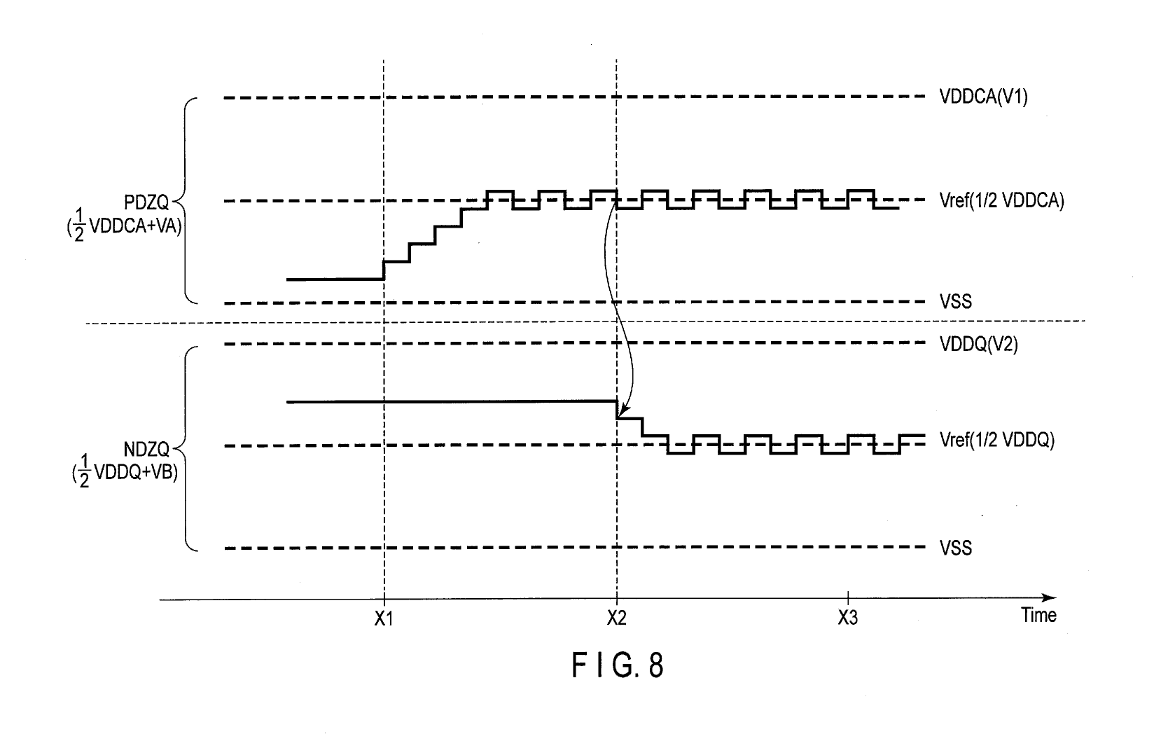

FIG. 8 is referred to for explanation of an operation example of the semiconductor device of the embodiment. Here, in addition to FIG. 8, FIG. 1 to FIG. 7 are also referred to for explanation of the operation of the semiconductor device of the present embodiment.

FIG. 8 is a timing chart schematically showing a relation between the voltage (the potential) of each node and time, to explain the operation example of the semiconductor device (e.g., the MRAM) of the present embodiment.

The ZQ command ZQC is issued from the controller 4 to the MRAM 1 simultaneously with the application of the power source voltages VDDCA, VDDQ to the MRAM 1. The power source voltage VDDCA is applied to the external resistance element RZQ, and the voltage is applied to the ZQ pad 89 via the external resistance element RZQ.

By the control of the control circuit 25 based on the ZQ command ZQC, the ZQ calibration operation to calibrate the impedance of the output buffer circuit 290 is started.

At a time X1, the ZQ calibration circuit 3 of the MRAM 1 of the present embodiment is driven. For example, most of circuits in the MRAM 1 except the ZQ calibration circuit 3 is in a standby state in a period from the start to the end of the ZQ calibration operation.

The calibration control circuit 39 and the first calibration code generation circuit 31 on the side of the VDDCA domain are driven by the control of the control circuit 25.

The calibration controller 391 controls the time counter 392. The time counter 392 starts counting the calibration time.

The calibration controller 391 supplies the initial code intNCD<n:0> to the counter circuit 312 of the first calibration code generation circuit 31.

The initial code intNCD<n:0> is supplied as the pre-calibration code pNCD<n:0> from the first counter circuit 312 to the first replica circuit 311. The on/off state of the N-type transistors TA are controlled in accordance with the initial code intNCD<n:0> as the pre-calibration code pNCD<n:0>. Among the N-type transistors TA having different channel lengths/channel widths, one or more N-type transistors TA are turned on in accordance with the initial code intNCD<n:0>. Additionally, at the start of the calibration, the number of the N-type transistors TA turned on in accordance with the initial code intNCD<n:0> is zero sometimes.

The voltage (the potential) of the node PDZQ varies in accordance with the number of the N-type transistors TA in the on-state. The voltage of the node PDZQ changes between, for example, the ground voltage VSS and the power source voltage VDDCA, and includes a variance value VA of a positive or negative size in accordance with the manufacturing conditions and operation environment of the MRAM and the state of the replica circuit 311. For example, the voltage of the node PDZQ is set to the size of half of the power source voltage VDDCA as the reference value based on the standard of the memory. In the following, the voltage of the node PDZQ will be written as ½VDDCA+VA. As regards a voltage ½VDDQ+VA, VA is a positive or negative value.

As an initial value of the potential of the node PDZQ, it is based on the voltage to be applied to the ZQ pad via the external resistance element (e.g., the resistance element of 240Ω) RZQ and the impedance (the drive ability) of the replica circuit 311.

The potential of the node PDZQ is supplied to the first comparison circuit 313. The potential of the node PDZQ is compared with the first reference voltage VrefCA (½VDDCA) by the first comparison circuit 313.

It is to be noted that in FIG. 8, the initial value of the potential of the node PDZQ is a value smaller than the reference voltage VrefCA. However, the initial value of the voltage ½VDDCA+VA of the node PDZQ is the reference voltage VrefCA or more sometimes.

In accordance with the comparison result of the voltage of the node PDZQ with the reference voltage VrefCA, the signal of the H level or the L level is output from the first comparison circuit 313 to the first counter circuit 312.

In accordance with the signal from the first comparison circuit 313, the value of the pre-calibration code pNCD is counted up or counted down by the first counter circuit 312.

The pre-calibration code pNCD subjected to the count-up processing or the count-down processing is supplied as the updated pre-calibration code pNCD to the N-type transistor TA of the replica circuit 311. The on/off state of the N-type transistors TA are switched by the updated pre-calibration code pNCD.

In accordance with the switching of the on/off state of the N-type transistor TA, the size of the output of the replica circuit 311 changes. That is, the number and combination of the N-type transistors TA in the on-state change, and hence the impedance (the drive ability) of the first replica circuit 311 changes. As a result, the potential of the node PDZQ changes.

Such comparison processing and count processing (the feedback processing) in the first calibration code generation circuit 31 are successively repeated within the predetermined period, to determine the number and combination of the N-type transistors TA in the on-state so that the potential of the node PDZQ is substantially equal to the reference voltage VrefCA. In consequence, the pre-calibration code pNCD is updated and determined synchronously with the count operation of the time counter 392.

The period to determine the pre-calibration code pNCD is set by the control of the comparison circuit 313 in accordance with the signal from the time counter 392. For example, the period to determine the pre-calibration code pNCD is preset by the test step of the MRAM, or the like so that the deviation of the potential of the node PDZQ falls in a range of an allowable value based on the specification/standard of the memory.

It is to be noted that FIG. 8 shows an example where the potential of the node PDZQ rises from the side of the ground voltage VSS to the reference voltage VrefCA. However, generation processing of the pre-calibration code (the calibration operation on the side of the first calibration code generation circuit) is executed sometimes so that the potential of the node PDZQ descends from the side of the power source voltage VDDCA to the side of the reference voltage VrefCA. Furthermore, the generation processing of the pre-calibration code is executed sometimes so that the rising and descending of the potential of the node PDZQ are intermingled.

After the elapse of a predetermined period, the second calibration code generation circuit 32 is driven. For example, at a time X2 when the pre-calibration code pNCD is determined by the first calibration code generation circuit 31 on the side of the VDDCA domain, the calibration operation by the second calibration code generation circuit 32 on the side of the VDDQ domain is started. For example, the operation of the first calibration code generation circuit 31 (the comparison processing and count processing) is stopped by the calibration control circuit 39.

The pre-calibration code pNCD is transferred from the first calibration code generation circuit 31 to the second calibration code generation circuit 32. In the second calibration code generation circuit 32, the pre-calibration code pNCD is supplied to the second counter circuit 322, and the initial code intPCD from the calibration controller 391 is supplied to the third replica circuit 325.

At the start of the calibration operation of the second calibration code generation circuit 32, the calibration code NCD in which the pre-calibration code pNCD is reflected is used as the initial value, and the on/off state of one or more N-type transistors TB of the second replica circuit 321 are thereby controlled. The on/off state of the P-type transistors TC of the third replica circuit 325 are controlled by using, as the initial value, the calibration code PCD<n:0> based on the initial code intPCD.

The voltage of the node NDZQ changes in accordance with the number of the N-type transistors TB in the on-state and the number of the P-type transistors TC in the on-state. For example, the potential of the node NDZQ changes between the ground voltage VSS and the voltage VDDQ, and includes a variance value VB corresponding to the manufacturing conditions and operation environment of the MRAM and the states of the replica circuits 321, 325. For example, for the voltage of the node NDZQ, the size of the half of the power source voltage VDDCA is set as the reference value based on the standard of the memory. In the following, the voltage of the node NDZQ will be written as ½VDDQ+VB. Regarding the voltage ½VDDQ+VB, VB is a positive or negative value.

The voltage (the potential) of the node NDZQ is supplied to each of the second and third comparison circuits 323, 327. The voltage of the node NDZQ is compared with the reference voltage VrefDQ by each of the second and third comparison circuits 323, 327. It is to be noted that in FIG. 8, the initial value of the voltage ½VDDQ+VB of the node NDZQ is a value larger than the reference voltage VrefDQ. However, the initial value of the voltage of the node NDZQ is the reference voltage VrefDQ or less sometimes in accordance with the manufacturing conditions/operation environment of the MRAM and an initial state of the replica circuit.

The results of the comparisons by the second and third comparison circuits 323, 327 are supplied to the second and third counter circuits 322, 326, respectively.

In accordance with the comparison result (the signal of the H/L level) of the second comparison circuit 323, the count processing (the count-up processing or the count-down processing) of the second counter circuit 322 is executed. In consequence, the calibration code NCD is updated. In accordance with the comparison result (the signal of the H/L level) of the third comparison circuit 327, the count processing (the count-up processing or the count-down processing) of the third counter circuit 326 is executed. In consequence, the calibration code PCD is updated.

By the updated calibration codes NCD, PCD, the on/off states of the respective transistors TB, TC are controlled.

In accordance with the drive abilities of the respective transistors TB, TC in the on-state based on the updated calibration codes NCD, PCD, the voltage of the node NDZQ varies.

The varied voltage of the node NDZQ is compared with the reference voltage ½VrefDQ, and the comparison result is output to the counter circuits 322, 326. On the basis of the comparison result, the calibration codes NCD, PCD are counted up or counted down.

Such comparison processing and count processing in the second calibration code generation circuit 32 are successively repeated in the predetermined period, to determine the numbers and combinations of the N-type and P-type transistors TB, TC in the on-state so that the potential of the node NDZQ is substantially equal to the reference voltage VrefDQ.

At a timing (a time X3) when it is detected that the voltage of the node NDZQ is substantially constant, the end of the calibration operation is judged by the calibration control circuit 39.

The calibration codes NCD, PCD determined by the calibration circuit are held in, for example, the control circuit 25 of the MRAM 1 or the predetermined latch circuit (not shown).

By the calibration operation of the MRAM of the present embodiment, the on/off state of the N-type transistors TN of the pull-down circuit 50 and the P-type transistors TP of the pull-up circuit 55 are controlled, and the impedance of the output buffer circuit 290 is regulated on the basis of the calibration codes NCD, PCD during the use of the MRAM 1 by a user.

It is to be noted that the first and second calibration code generation circuits 31, 32 may be driven so that the processing of the first calibration code generation circuit 31 is executed in parallel with the processing of the second calibration code generation circuit 32.

In the MRAM 1 of the present embodiment, a part 32 of the calibration circuit 3 is disposed in the vicinity of the output buffer circuit 290 and the DQ pad 85.

In a control method of the MRAM 1 of the present embodiment, the regulation of the impedance of the output buffer circuit 290 by the ZQ calibration operation is executed by driving the calibration circuit 3, which is formed under similar manufacturing conditions as for the output buffer circuit 290, under a similar operation environment as in the output buffer circuit 290.

According to the control method of the MRAM of the present embodiment, by the second calibration code generation circuit 32 in the same voltage region (forming region) DomDQ as the DQ pad 85 and the input/output circuit 29, the calibration codes NCD, PCD of the impedance of the output buffer circuit (the output driver circuit) 290 based on the voltage VDDQ are substantially generated and determined.

According to the control method of the MRAM of the present embodiment, the accuracy of the calibration of the impedance of the output buffer circuit 290 by the ZQ calibration improves.

Therefore, the control method of the semiconductor device of the present embodiment can improve the reliability of the operation of the circuit.

### (2) Modifications

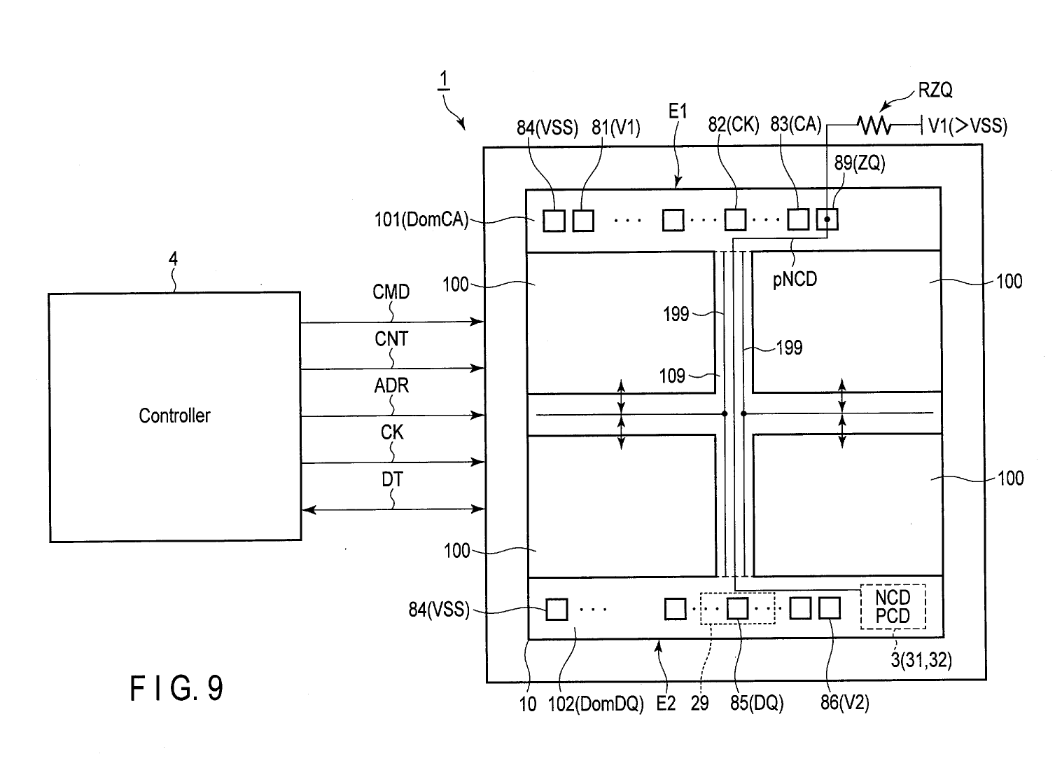

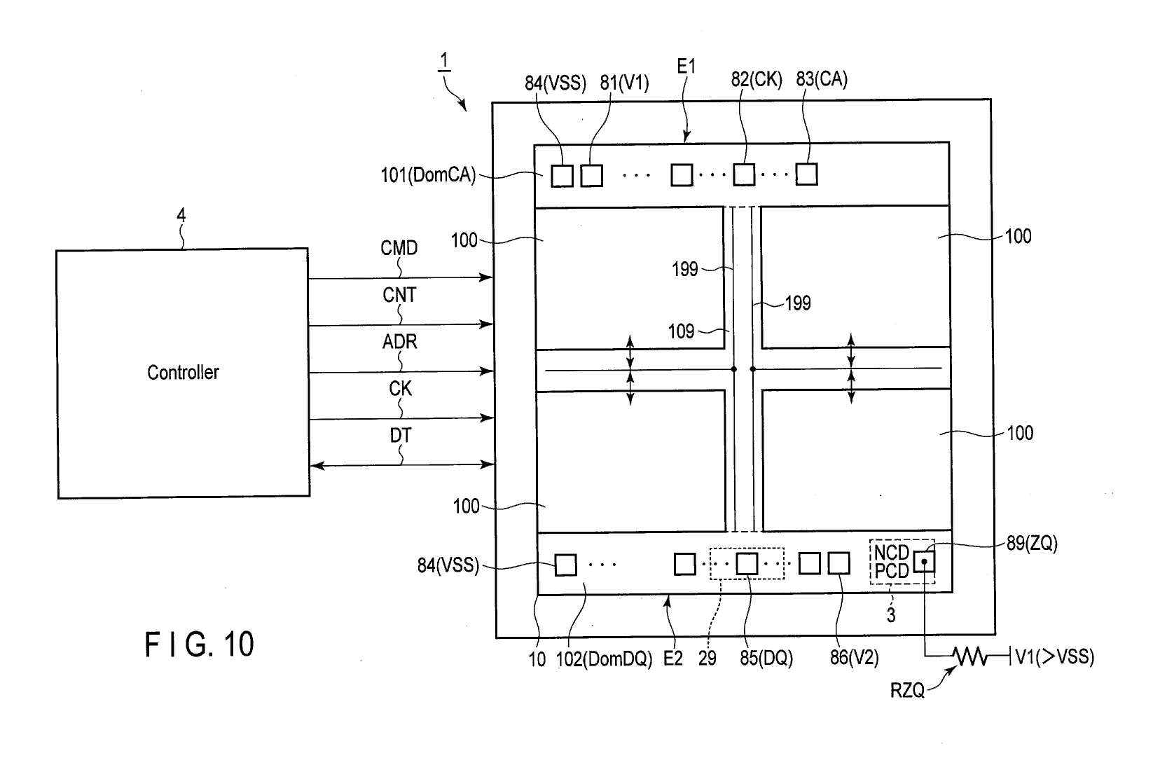

FIG. 9 and FIG. 10 are referred to for explanation of modifications of the semiconductor device of the present embodiment. It is to be noted that in the present modification, elements having the same functions and configurations as in the semiconductor device of FIG. 1 to FIG. 8 are denoted with the same reference symbols, and redundant descriptions are omitted.

FIG. 9 and FIG. 10 are plan views showing chip layouts to explain the modifications of the semiconductor device (e.g., an MRAM) of the present embodiment, respectively.

As shown in FIG. 9, a ZQ calibration circuit 3 may entirely be disposed in the vicinity of a DQ pad 85 of a chip of the MRAM.

The ZQ calibration circuit 3 is disposed in a VDDQ domain DomDQ (e.g., a pad arrangement region 102) which is the same region as a region including an output buffer circuit 290.

As shown in FIG. 10, similarly to a ZQ calibration circuit 3, a ZQ pad 89Z may be disposed in a VDDQ domain DomDQ which is the same region as a region including an output buffer circuit 290.

The ZQ pad 89Z is disposed in a pad arrangement region 102 which is the same region as a region including a DQ pad 85.

In an MRAM 1 of FIG. 10, a voltage VDDQ can be applied to an external resistance element RZQ. For example, in the MRAM 1 of FIG. 10, a first calibration code generation circuit 31 of the ZQ calibration circuit 3 can be omitted. Furthermore, when the ZQ pad 89 and the ZQ calibration circuit 3 are disposed in a region of the vicinity of the output buffer circuit 290, an internal configuration of the ZQ calibration circuit may be different from a configuration shown in FIG. 7, as long as the execution of the ZQ calibration is possible.

The semiconductor devices of the modifications shown in FIG. 9 and FIG. 10 can obtain the same effect as in the semiconductor device of the embodiment.

### (3) Others

In the abovementioned respective embodiments, an MRAM is illustrated as a semiconductor memory. However, the semiconductor memory of the embodiment is not limited to the MRAM. For example, a calibration circuit for regulation of an impedance of an output circuit in the present embodiment may be applied to another semiconductor memory such as an SRAM, a DRAM, a ReRAM, a PCRAM or a flash memory, as long as a circuit is a semiconductor circuit including a pad (a ZQ pad in the present embodiment) for use during the regulation of the impedance of the output circuit. Furthermore, a semiconductor device including a calibration circuit 3 of the present embodiment may be a logic circuit or an image sensor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first pad disposed in a first region between a memory region of a semiconductor chip and a first end portion of the semiconductor chip;
a second pad disposed in a second region between the memory region and a second end portion of the semiconductor chip, the second end portion being opposite to the first end portion;
an output circuit coupled to the second pad; and
a calibration circuit which is coupled to the first pad and regulates an impedance of the output circuit, the calibration circuit including a first circuit disposed in the first region and a second circuit disposed in the second region.

2. The device according to claim 1,
wherein a first voltage larger than a ground voltage is applied to the first pad from an outside of the semiconductor chip via an external resistance element,
the first pad is a reference node to regulate the impedance of the output circuit, and
the external resistance element has a reference resistance value corresponding to the impedance of the output circuit.

3. The device according to claim 2,
wherein the output circuit includes a pull-down circuit and a pull-up circuit,
the first circuit generates a first calibration code to regulate an impedance of the pull-down circuit on the basis of the first voltage, and
the second circuit generates a second calibration code to regulate the impedance of the pull-down circuit on the basis of the first calibration code and a second voltage larger than the grand voltage, and a third calibration code to regulate an impedance of the pull-up circuit on the basis of the second voltage.

4. The device according to claim 3,
wherein the first circuit includes a first replica circuit corresponding to the pull-down circuit, and
the second circuit includes a second replica circuit corresponding to the pull-down circuit, and a third replica circuit corresponding to the pull-up circuit.

5. The device according to claim 4,
wherein one end of the first replica circuit is coupled to the first pad,
one end of the second replica circuit is coupled to one end of the third replica circuit,
the first voltage is applied to the one end of the first replica circuit via the first pad and the external resistance element,
the ground voltage is applied to the other end of the first replica circuit,
the ground voltage is applied to the other end of the second replica circuit, and
the second voltage is applied to the other end of the third replica circuit.

6. The device according to claim 4,
wherein the first replica circuit includes first transistors connected in parallel,
the second replica circuit includes second transistors connected in parallel,
the third replica circuit includes third transistors connected in parallel,
the first transistors have a first conductivity type,
the second transistors have the first conductivity type, and
the third transistors have a second conductivity type different from the first conductivity type.

7. The device according to claim 6,
wherein each of first signals in the first calibration code is supplied to each of gates of the first transistors,
each of second signals in the second calibration code is supplied to each of gates of the second transistors, and
each of third signals in the third calibration code is supplied to each of gates of the third transistors.

8. The device according to claim 6,
wherein the first transistors are N-channel type field effect transistors,
the second transistors are the N-channel type field effect transistors, and
the third transistors are P-channel type field effect transistors.

9. The device according to claim 4,
wherein the first circuit includes a first connection node between the first pad and the first replica circuit,
the second circuit includes a second connection node between the second replica circuit and the third replica circuit,
the first circuit includes a first comparison circuit which compares a first reference voltage with a voltage of the first connection node, and
the second circuit includes second and third comparison circuits which compare a second reference voltage with a voltage of the second connection node.

10. The device according to claim 9,
wherein the first circuit includes a first counter circuit connected between an output terminal of the first comparison circuit and a control terminal of the first replica circuit,
the second circuit includes a second counter circuit connected between an output terminal of the second comparison circuit and a control terminal of the second replica circuit, and a third counter circuit connected between an output terminal of the third comparison circuit and a control terminal of the third replica circuit.

11. The device according to claim 10,
wherein the first counter circuit updates a value of the first calibration code on the basis of a comparison result of the first comparison circuit,
the second counter circuit updates a value of the second calibration code on the basis of a comparison result of the second comparison circuit, and
the third counter circuit updates a value of the third calibration code on the basis of the comparison result of the third comparison circuit.

12. The device according to claim 3,
wherein the calibration circuit includes a calibration control circuit to control the first and second circuits, and
the calibration circuit supplies an initial code of the first calibration code to the first circuit, and supplies an initial code of the third calibration code to the second circuit.

13. The device according to claim 1,
wherein the memory region includes a magnetoresistive effect element as a memory element.

14. The device according to claim 1,
wherein each of the first voltage and the second voltage is 1.0 V or more and 1.5 V or less.

15. A semiconductor device comprising:
a first region disposed between a memory region of a semiconductor chip and a first end portion of the semiconductor chip;
a second region disposed between the memory region and a second end portion of the semiconductor chip, the second end portion being opposite to the first end portion;
an output circuit disposed in the second region; and
a calibration circuit which is disposed in the second region and regulates an impedance of the output circuit.

16. The device according to claim 15, further comprising:
a first pad disposed in the second region and coupled to the calibration circuit, the first pad coupled to an external resistance element, the external resistance element having a reference resistance value corresponding to the impedance of the output circuit.

17. The device according to claim 15, further comprising:
a first pad disposed in the first region and coupled to the calibration circuit, the first pad coupled to an external resistance element, the external resistance element having a reference resistance value corresponding to the impedance of the output circuit.

18. The device according to claim 15, further comprising:
a second pad disposed in the second region and coupled to the output circuit.

19. The device according to claim 16,
wherein the memory region includes a magnetoresistive effect element as a memory element.
